(19) United States
(12) Patent Application Publication
(10) Pub. No.: US 2021/0242102 A1
(43) Pub. Date: Aug. 5, 2021

(54) UNDERFILL MATERIAL FOR INTEGRATED CIRCUIT (IC) PACKAGE

(71) Applicant: Intel Corporation, Santa Clara, CA (US)

(72) Inventors: Elizabeth NOFEN, Phoenix, AZ (US); Ziyin LIN, Chandler, AZ (US); Nisha ANANTHAKRISHNAN, Chandler, AZ (US)

(21) Appl. No.: 16/781,894

(22) Filed: Feb. 4, 2020

(51) Int. Cl. H01L 23/31; H05K 1/18; C08L 63/00; C08L 75/04; C08L 67/00; C08L 83/04; C08K 5/3432; C08K 3/36; C08K 3/22; C08K 3/38; H01L 23/50

(52) U.S. Cl. CPC H01L 23/3178; C08L 25/06; C08L 63/00; C08L 75/04; C08L 67/00; C08L 83/04; C08K 5/3432; C08K 3/36; C08K 3/22; C08K 3/38; H01L 23/50; C08K 2003/2296; C08K 2003/2227; C08K 2003/385; H05K 1/185

(57) ABSTRACT

Embodiments herein describe techniques for an IC package including an electronic component, and an underfill material around or below the electronic component to support the electronic component. The underfill material includes a resin and a thermolatent onium salt as a cationic cure for the underfill material. The thermolatent onium salt comprises an organic cation with a heteroatom center, and an anion including metalloid fluoride. The heteroatom center includes an iodonium, sulphonium, phosphonium, or N-containing onium. Other embodiments may be described and/or claimed.

### FIELD

Embodiments of the present disclosure generally relate to the field of integrated circuit (IC), and more particularly, to IC packages.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

An electronic component, e.g., an integrated circuit (IC) chip or a die, may be coupled with other electronic components using an IC package that can be attached to a printed circuit board (PCB). Various packing technologies, e.g., flip-chip packages, complex system-in-packages (SiPs), multi-chip packages (MCPs), and more, have been developed. Underfill encapsulation plays a significant role in the protection and reliability of flip-chip packages or other kinds of packages. Underfill can reduce the effect of the global thermal expansion mismatch between the silicon chip and the substrate. Void-free underfill is important to prevent solder extrusion during subsequent assembly processes and to ensure reliability performance of a package. Recent packaging trends towards heterogeneous integration in MCP make void-free underfill increasingly challenging for packages.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1(a)-1(b) schematically illustrate an example integrated circuit (IC) package including an underfill material having thermolatent onium salt as a cationic cure, in accordance with various embodiments.

FIG. 2 schematically illustrates a process for forming an IC package including an underfill material having thermolatent onium salt as a cationic cure, in accordance with various embodiments.

FIG. 3 schematically illustrates a package substrate implementing one or more embodiments of the disclosure, in accordance with various embodiments.

FIG. 4 schematically illustrates a computing device built in accordance with an embodiment of the disclosure, in accordance with various embodiments.

### DETAILED DESCRIPTION

An integrated circuit (IC) package, which may also be referred to as a microelectronics package, or simply a package, may include one or more electronic components or components, e.g., an IC chip or a die, placed on a package substrate, which may be further attached to a printed circuit board (PCB). Components are used here broadly, which may refer to any object in a package, e.g., printed circuit board (PCB), an interposer, a patch, a packaging substrate, a chip, a die, a wafer, or other components. Underfill encapsulation plays a significant role in the protection and reliability of flip-chip packages or other kinds of packages. Void-free underfill, referring to no void formed in the underfill material, is important and desired to ensure reliability performance of a package. For some recent packaging technology, e.g., multi-chip packages (MCPs) including multiple large dies and small dies, void-free underfill is increasingly challenging to achieve for various reasons. For example, compared to other packages, a MCP package may have longer flow distances, e.g., flow distances of about 50 mm, with tighter pitches, which may cause slow underfill flow and longer flow time, e.g., flow time of about 30 min. In addition, underfill void can be caused by pitch transition regions and de-populated die areas in a MCP package. The current underfill material may not have enough flow distance and flow time to serve the need of some MCP packages. In detail, some current underfill material may have a maximum flow distance of 28 mm and a maximum flow time of 10 to 15 min, which are not enough to serve the need for MCP packages. High pressure cure (HPC) has been used in the industry to facilitate collapse of trapped voids in underfill by trapped air diffusion into the liquid resin of the underfill before cure. However, current HPC techniques have limited effectiveness.

Traditional underfill material may include various materials, e.g., filler, resin, hardeners, or other materials. Improvements of underfill material may include optimizing the filler and resin types, loadings, chemistries, or other ways. Commonly used underfill chemistries may include epoxy-amine, epoxy-anhydride, epoxy-phenol, etc. Fundamental reactions of these chemistries occur or start to occur at temperatures of 100-150° C. Hence, such underfill chemistries may not have high temperature thermal stability. Some other approaches may use latent cure chemistries for underfill material. However, currently used latent cure chemistries of underfill may be targeted for longer ambient temperature pot life for dispense of the underfill material, which is difficult to have high temperature (e.g., >150° C.) stability. As a result, current underfill materials have limited flow distance, flow time, and limited HPC effectiveness.

Embodiments herein present underfill materials typically based on, but not limited to, epoxy materials, used in IC packages. The underfill material may be pre B-stage or B-staged during the packaging process. IC packages include an underfill material having thermolatent onium salt as a cationic cure. The resin system of the underfill is catalyzed by the thermolatent onium salt as a cationic cure. An underfill material having thermolatent onium salt as catalyst can achieve latent cure onset, and further allow for full cure of the underfill material at end of line. As a result, the underfill material presented herein may have a longer flow distance, a longer high temperature flow time, longer high temperature stability before the gel point is reached, and a longer time in high-pressure oven cure before gelling to allow for improved flow distance and void collapse. Hence, the underfill materials presented herein can improve HPC effectiveness. In some embodiments, an underfill material may not have any of the typical hardeners (amine, anhydride, phenol, etc.) contained in a conventional underfill material. An underfill material without hardener can have lower cure outgassing, which can additionally reduce potential void formed in the underfill. Cationic cure chemistry for underfill materials presented herein can be applied to both capillary and pre-applied underfill formulations, for any interconnect level, including, but not limited to first level, second level, and board level interconnects.

Embodiments herein may present an IC package including an electronic component, and an underfill material around or below the electronic component to support the electronic component. The underfill material includes a resin and a thermolatent onium salt as a cationic cure for the underfill material. The thermolatent onium salt comprises an organic cation with a heteroatom center, and an anion including metalloid fluoride. The heteroatom center includes an iodonium, sulphonium, phosphonium, or N-containing onium.

In embodiments, a method for forming an IC package is presented. The method includes providing an assembly of the IC package. The assembly includes a first component with a first surface, a second component with a second surface placed opposite to the first surface of the first component to form a space between the first component and the second component. The assembly further includes a connector within the space between the first component and the second component. The method further includes providing an underfill material within the space and around the connector. The underfill material includes a resin and a thermolatent onium salt as a cationic cure for the underfill material. The thermolatent onium salt comprises an organic cation with a heteroatom center, and an anion including metalloid fluoride. The heteroatom center includes an iodonium, sulphonium, phosphonium, or N-containing onium.

Embodiments herein may present a computing device, which may include a first component with a first surface, and a second component with a second surface placed opposite to the first surface of the first component to form a space between the first component and the second component. The computing device further includes a connector within the space between the first component and the second component. An underfill material is within the space and around the connector. The underfill material includes a resin and a thermolatent onium salt as a cationic cure for the underfill material. The thermolatent onium salt comprises an organic cation with a heteroatom center, and an anion including metalloid fluoride. The heteroatom center includes an iodonium, sulphonium, phosphonium, or N-containing onium.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, zinc oxide or other combinations of group III-V, group II-VI, group IV, or semiconducting oxide materials. Although a few examples of materials from which the substrate may be formed are described here, any material that may serve as a foundation upon which a semiconductor device may be built falls within the spirit and scope of the present disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process operations. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in-situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

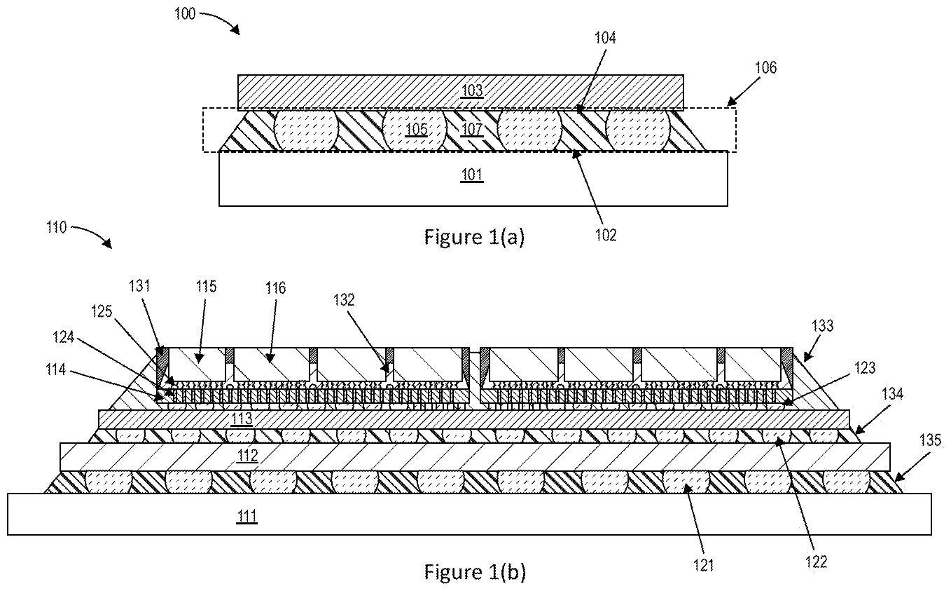

FIGS. 1(a)-1(b) schematically illustrate an example integrated circuit (IC) package including an underfill material having thermolatent onium salt as a cationic cure, in accordance with various embodiments. FIG. 1(a) shows an assembly 100 of an IC package that includes an underfill material 107 having thermolatent onium salt as a cationic cure. FIG. 1(b) shows an IC package 110 that includes underfill materials at various locations.

As shown in FIG. 1(a), the assembly 100 is a part of an IC package, e.g., the IC package 110 shown in FIG. 1(b). The assembly 100 includes a first component 101 with a first surface 102, a second component 103 with a second surface 104 placed opposite to the first surface 102 of the first component 101 to form a space 106 between the first component 101 and the second component 103. One or more connectors, e.g., a connector 105, are within the space 106 between the first component 101 and the second component 103. The underfill material 107 is within the space 106 and around the connector 105.

In embodiments, the first component 101 or the second component 103 may be a PCB, an interposer, a patch, a packaging substrate, a chip, a die, a wafer, a supporting layer for a chip, or other electronic components. The first component 101 or the second component 103 may include various layers, e.g., a solder resist layer, a metal layer, a mold layer, a core layer, a dielectric layer, an insulated polymer layer, a silicon substrate, a polymeric substrate, a non-polymeric substrate, a silicon substrate, a silicon on insulator (SOI) substrate, a silicon on sapphire (SOS) substrate. The first component 101 or the second component 103 may include various materials, e.g., organic resin, inorganic filler, a conductive material, an epoxy with fillers such as silica and with glass fiber weave made out of silica, or a buildup material that is also made out of epoxy with silica or magnesia fillers.

In embodiments, as shown in FIG. 1(b), the IC package 110 includes an electronic component, e.g., a die 115 or a die 116, and an underfill material around or below the electronic component to support the electronic component. The IC package 100 may be a chip scale package (CSP), a wafer-level package (WLP), a stacked IC package, a system-in-package (SiP), a multi-chip package (WCP), a quad-flat no-leads (QFN) package, a dual-flat no-leads (DFN) package, a flip chip package, or a ball grid array (BGA) package. In embodiments, the IC package 110 may be a part of wearable device or a mobile computing device. In addition, not shown, the wearable device or the mobile computing device may include one or more of an antenna, a touchscreen controller, a display, a battery, a processor, an audio codec, a video codec, a power amplifier, a global positioning system (GPS) device, a compass, a Geiger counter, an accelerometer, a gyroscope, a speaker, and a camera coupled with the memory device.

The assembly 100 may be a part of the IC package 110. For example, the first component 101 may be a PCB 111, the second component 103 may be an interposer 112, the connector 105 may be a solder joint 121, and the underfill material 107 is located at a PCB level interconnect 135. Additionally and alternatively, the first component 101 may be the interposer 112, the second component 103 may be a patch 113, the connector 105 may be a solder bump 122, and the underfill material 107 is located at a mid-level interconnect 134. Furthermore, the first component 101 may be the patch 113, the second component 103 may be a substrate 114, the connector 105 may be a micro bump 123, and the underfill material 107 is located at first level interconnect 133. Moreover, the first component 101 may be the substrate 114 and the second component 103 may be the die 115, the connector 105 may be a combination of a contact 125 and a through via 124, and the underfill material 107 is located at a logic to logic interconnect 132. In addition, the underfill material 107 may be within a space between two dies, the die 115 and the die 116. The IC package 110 may further include an overmold 131 covering the logic to logic interconnect 132.

In embodiments, the underfill material 107 includes a resin and a thermolatent onium salt as a cationic cure for the underfill material. The underfill material 107 may include a thermolatent onium salt with a concentration level greater than or equal to 0.5 wt %. The underfill material 107 may include Sb, F, As, P, B, or I at a concentration level greater than or equal to 100 ppm. The underfill material 107 may further include silica, alumina, boron nitride, zinc oxide, or a filler material. The underfill material 107 may further include colorants, inhibitors, ion trappers, stress absorbers, polymers, surfactants, binding agents, fluxing agents, or additives. In some embodiments, the underfill material 107 may not include an amine type hardener, an anhydride type hardener, or a phenol type hardener. The underfill material 107 may be a film, liquid, or powder form before cured on the IC package. The underfill material 107 may be applied on the IC package by dispensing, printing, curtain coating, molding, or lamination. The underfill material 107 may have a flow distance in a range of about 20 mm to about 50 mm, a flow time in a range of about 10 min to about 30 min, and is stable at a temperature greater than 150° C.

The underfill material 107 includes a resin and a thermolatent onium salt as a cationic cure for the underfill. The resin may include epoxy resin, acrylates, bismaleimides, polyesters, polyimides, polyolefins, polystyrene, polyurethanes, polyurethane resin, silicone resin, or polyester resin. In detail, the thermolatent onium salt may include an organic cation with a heteroatom center, and an anion including metalloid fluoride. The heteroatom center may include an iodonium, sulphonium, phosphonium, or N-containing onium. In some embodiments, the organic cation further includes a benzyl moiety. The benzyl moiety may include benzylsulfonium, benzylammonium, benzylphosphonium, or benzylpyrazinium, which release a carbocation or a protonated benzylic methylene initiating species and lead to strong electrophilic bronsted acids to initiate the polymerization. When the temperature is above 180° C., the onium salt is broken open to release the metal superacid catalyst and begin the cationic epoxy polymerization reaction. Additionally, using non-nucleophilic anions in onium salts allows for improved rates of polymerization, i.e., SbF₆⁻>AsF₆⁻>PF₆⁻>BF₄⁻>>I⁻ or Cl⁻ for the cationic initiator.

The underfill material 107 having thermolatent onium salt as catalyst can achieve latent cure onset, and further allow for full cure of the underfill material 107 at end of line. The thermolatent onium salt catalyst in the underfill material 107 helps to shift the cure initiation to higher temperatures by employing a chain-growth epoxy, leading to longer flow distances and improved HPC effectiveness. As a result, the underfill material 107 has a longer flow distance, longer high temperature flow time, longer high temperature stability before the gel point is reached, and longer time in high-pressure oven cure before gelling to allow for improved flow distance and void collapse. Hence, the underfill material 107 can improve HPC effectiveness. In addition, when the underfill material 107 does not have hardener, the underfill material 107 has lower cure outgassing, which can additionally reduce potential void formed in the underfill material.

The underfill material 107 contains elements and ions not contained in a traditional or typical underfill material. A current Plan of Record (POR) underfill (UF) material contains small to none F, e.g., <1. In an embodiment, the underfill material 107 including a thermolatent onium salt with the SbF₆⁻ anion contains much more F, e.g., 345. Similarly, a POR UF material does not contain any Sb, while the underfill material 107 including a thermolatent onium salt with the SbF₆⁻ anion contains 0.9 Sb.

In embodiments, a POR UF starts to gel at about 10 mins after staging at 150° C. On the other hand, the underfill material 107 may have a negligible change in viscosity at 150° C. for 30 min, which shows the effectiveness of the underfill material 107 for extended thermal stability that allows for longer flow time at elevated temperatures and a longer time in HPC to allow for void collapse before gelling.

In embodiments, a POR UF may have a 5° C./min ramp onset/peak at 129.30/173.78° C. Hence, the POR UF begins to form cross-links and have limited thermal stability. On the other hand, the underfill material 107 has an onset of 198.16° C. and a peak of 202.42° C. Hence, the underfill material 107 has no reaction before 170° C., allowing for excellent 150° C. stability, and also shows high temperature snap cure functionality, with the onset and peak being only ˜4° C. apart for the 5° C./min ramp rate.

In some embodiments, the underfill material 107 has only about 0.5% weight loss after 225° C. 15 min exposure, where the weight loss is caused by water vapor, carbon dioxide, methanol and unknown gases of low concentration as the outgas products. On the other hand, a POR UF has about 1.7% weight loss for the same condition, and a clear signal of the loss of 1, 2-epoxy-3-phenoxypropane and ethylaniline.

In general, the flow distance and flow time of the underfill material 107 may be related to the features of the IC package the underfill material flow under or around, the flow properties and the cure kinetics of the underfill material. If an underfill material is curing too fast, the underfill material may gel and stop flowing before the desired flow length or die filling is achieved. The use of the latent cationic cure catalyst in the underfill material 107 allows for extended time at the elevated flow temperature before the material gels, to enable underfilling of these complex architectures with increasingly long flow lengths.

In embodiments, there may be little or no bump corrosion when the underfill material 107 is used. In addition, the underfill material 107 may cause only limited solder wing growth similar to the current POR UF materials.

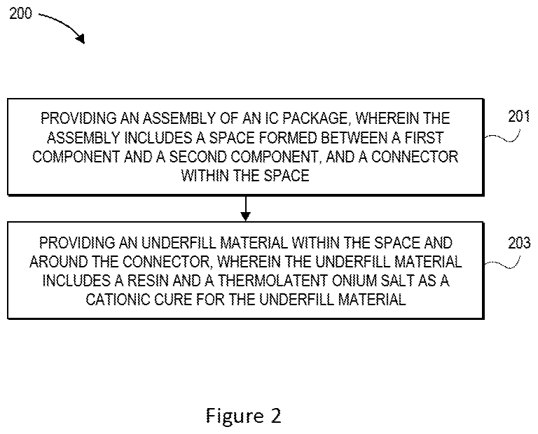

FIG. 2 schematically illustrates a process 200 for forming an IC package including an underfill material having thermolatent onium salt as a cationic cure, in accordance with various embodiments. In embodiments, the process 200 may be applied to form the IC package 110 shown in FIG. 1(b) that includes the assembly 100 shown in FIG. 1(a).

At block 201, the process 200 may include providing an assembly of an IC package, wherein the assembly includes a space formed between a first component and a second component, and a connector within the space. The first component or the second component may be a printed circuit board (PCB), an interposer, a patch, a packaging substrate, a chip, a die, or a wafer. The connector may be a solder joint, a solder bump, a micro bump, a ball, a pin, or a through via. For example, as shown in FIG. 1(a), the process 200 may be applied to provide the assembly 100 of an IC package. The assembly 100 includes the space 106 formed between the first component 101 and the second component 103, and the connector 105 within the space 106.

At block 203, the process 200 may include providing an underfill material within the space and around the connector, where the underfill material includes a resin and a thermolatent onium salt as a cationic cure for the underfill material. The underfill material may be provided by dispensing the underfill material, printing the underfill material, curtain coating the underfill material, molding the underfill material, or laminating the underfill material. For example, as shown in FIG. 1(a), the process 200 may be applied to provide the underfill material 107 within the space 106 and around the connector 105, where the underfill material 107 includes a resin and a thermolatent onium salt as a cationic cure for the underfill material.

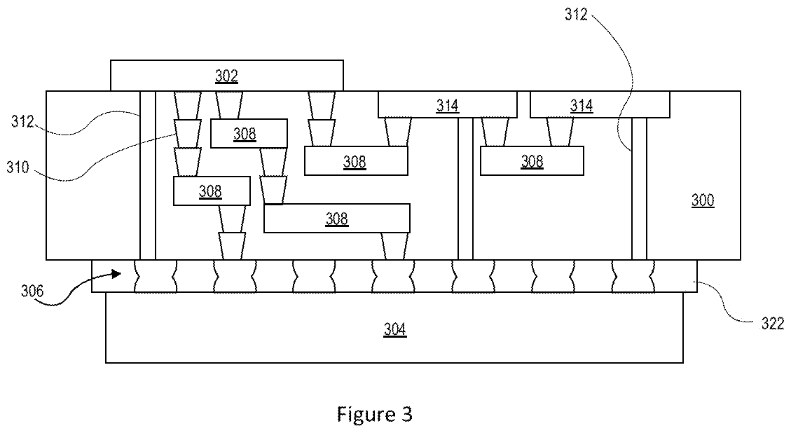

FIG. 3 schematically illustrates a package substrate 300 implementing one or more embodiments of the disclosure, in accordance with some embodiments. The package substrate 300 is an intervening substrate used to bridge a first substrate 302 to a second substrate 304. The first substrate 302 may be, for instance, a substrate support for a die. The second substrate 304 may be, for instance, a memory module, a computer motherboard, or a PCB. For example, a package substrate 300 may couple an integrated circuit die to a ball grid array (BGA) 306 that can subsequently be coupled to the second substrate 304. In some embodiments, the first and second substrates 302/304 are attached to opposing sides of the package substrate 300. In other embodiments, the first and second substrates 302/304 are attached to the same side of the package substrate 300. And in further embodiments, three or more substrates are interconnected by way of the package substrate 300.

There may be underfill material between the first substrate 302 and the package substrate 300, or between the second substrate 304 and the package substrate 300. For example, an underfill material 322 is between the second substrate 304 and the package substrate 300. The underfill material 322 may be an example of the underfill material 107 shown in FIG. 1(a). The underfill material 322 includes a resin and a thermolatent onium salt as a cationic cure for the underfill material, wherein the thermolatent onium salt comprises an organic cation with a heteroatom center, and an anion including metalloid fluoride, and wherein the heteroatom center includes an iodonium, sulphonium, phosphonium, or N-containing onium.

The package substrate 300 may be formed of an epoxy resin, a fiberglass-reinforced epoxy resin, a ceramic material, or a polymer material such as polyimide. In further implementations, the package substrate may be formed of alternate rigid or flexible materials that may include the same materials described above for use in a semiconductor substrate, such as silicon, germanium, and other group III-V and group IV materials.

The package substrate may include metal interconnects 308 and vias 310, including but not limited to through-silicon vias (TSVs) 312. The package substrate 300 may further include embedded devices 314, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the package substrate 300.

In accordance with embodiments of the disclosure, apparatuses or processes disclosed herein may be used in the fabrication of package substrate 300.

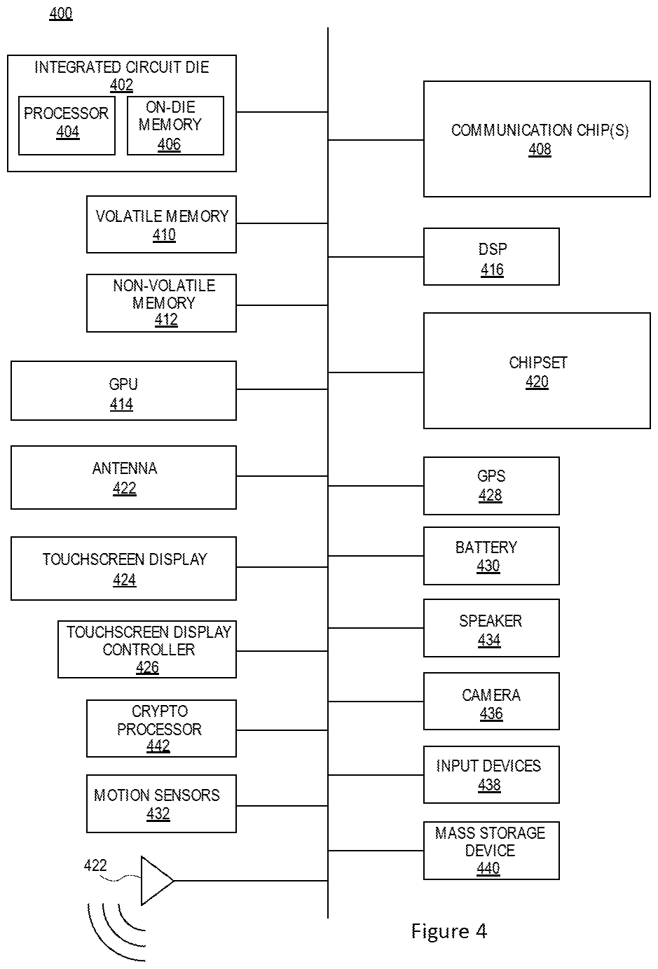

FIG. 4 illustrates a computing device 400 in accordance with one embodiment of the disclosure. The computing device 400 may include a number of components. In one embodiment, these components are attached to one or more motherboards. In an alternate embodiment, some or all of these components are fabricated onto a single system-on-a-chip (SoC) die, such as a SoC used for mobile devices. The components in the computing device 400 include, but are not limited to, an integrated circuit die 402 and at least one communications logic unit 408. In some implementations the communications logic unit 408 is fabricated within the integrated circuit die 402 while in other implementations the communications logic unit 408 is fabricated in a separate integrated circuit chip that may be bonded to a substrate or motherboard that is shared with or electronically coupled to the integrated circuit die 402. The integrated circuit die 402 may include a processor 404 as well as on-die memory 406, often used as cache memory, which can be provided by technologies such as embedded DRAM (eDRAM), or SRAM. For example, the on-die memory 406, the processor 404, or the integrated circuit die 402 may be placed on a packaging substrate. An underfill material may exist between the integrated circuit die 402, the on-die memory 406, the processor 404, and the packaging substrate, where the underfill material may be an example of the underfill material 107 shown in FIG. 1(a). In embodiments, the computing device 400 may include a display or a touchscreen display 424, and a touchscreen display controller 426. A display or the touchscreen display 424 may include a FPD, an AMOLED display, a TFT LCD, a micro light-emitting diode (μLED) display, or others.

Computing device 400 may include other components that may or may not be physically and electrically coupled to the motherboard or fabricated within a SoC die. These other components include, but are not limited to, volatile memory 410 (e.g., dynamic random access memory (DRAM), non-volatile memory 412 (e.g., ROM or flash memory), a graphics processing unit 414 (GPU), a digital signal processor (DSP) 416, a crypto processor 442 (e.g., a specialized processor that executes cryptographic algorithms within hardware), a chipset 420, at least one antenna 422 (in some implementations two or more antenna may be used), a battery 430 or other power source, a power amplifier (not shown), a voltage regulator (not shown), a global positioning system (GPS) device 428, a compass, a motion coprocessor or sensors 432 (that may include an accelerometer, a gyroscope, and a compass), a microphone (not shown), a speaker 434, a camera 436, user input devices 438 (such as a keyboard, mouse, stylus, and touchpad), and a mass storage device 440 (such as hard disk drive, compact disk (CD), digital versatile disk (DVD), and so forth). The computing device 400 may incorporate further transmission, telecommunication, or radio functionality not already described herein. In some implementations, the computing device 400 includes a radio that is used to communicate over a distance by modulating and radiating electromagnetic waves in air or space. In further implementations, the computing device 400 includes a transmitter and a receiver (or a transceiver) that is used to communicate over a distance by modulating and radiating electromagnetic waves in air or space.

The communications logic unit 408 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 408 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 400 may include a plurality of communications logic units 408. For instance, a first communications logic unit 408 may be dedicated to shorter range wireless communications such as Wi-Fi, NFC, and Bluetooth and a second communications logic unit 408 may be dedicated to longer range wireless communications such as GPS, EDGE, GPRS, CDMA, WiMAX, LTE, Ev-DO, and others.

The processor 404 of the computing device 400 includes one or more devices, such as transistors. The term “processor” may refer to any device or portion of a device that processes electronic data from registers and/or memory to transform that electronic data into other electronic data that may be stored in registers and/or memory. The communications logic unit 408 may also include one or more devices, such as transistors.

In further embodiments, another component housed within the computing device 400 may contain one or more devices, such as DRAM, that are formed in accordance with implementations of the current disclosure. In various embodiments, the computing device 400 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

Some non-limiting Examples are provided below.

Example 1 may include an integrated circuit (IC) package, comprising: an electronic component; and an underfill material around or below the electronic component to support the electronic component, wherein the underfill material includes a resin and a thermolatent onium salt as a cationic cure for the underfill material, wherein the thermolatent onium salt comprises an organic cation with a heteroatom center, and an anion including metalloid fluoride, and wherein the heteroatom center includes an iodonium, sulphonium, phosphonium, or N-containing onium.

Example 2 may include the IC package of example 1 and/or some other examples herein, wherein the organic cation further includes a benzyl moiety.

Example 3 may include the IC package of example 2 and/or some other examples herein, wherein the benzyl moiety includes benzylsulfonium, benzylammonium, benzylphosphonium, or benzylpyrazinium.

Example 4 may include the IC package of example 1 and/or some other examples herein, wherein the anion includes SbF₆, AsF₆, PF₆, or BF₄.

Example 5 may include the IC package of example 1 and/or some other examples herein, wherein the thermolatent onium salt includes N-benzylpyrazinium hexafluoroantimonate.

Example 6 may include the IC package of example 1 and/or some other examples herein, wherein the resin is epoxy resin, acrylates, bismaleimides, polyesters, polyimides, polyolefins, polystyrene, polyurethanes, polyurethane resin, silicone resin, or polyester resin.

Example 7 may include the IC package of example 1 and/or some other examples herein, wherein the underfill material does not include an amine type hardener, an anhydride type hardener, or a phenol type hardener.

Example 8 may include the IC package of example 1 and/or some other examples herein, wherein the underfill material includes the thermolatent onium salt with a concentration level greater than or equal to 0.5 wt %.

Example 9 may include the IC package of example 1 and/or some other examples herein, wherein the underfill material includes Sb, F, As, P, B, or I at a concentration level greater than or equal to 100 ppm.

Example 10 may include the IC package of example 1 and/or some other examples herein, wherein the underfill material further includes silica, alumina, boron nitride, zinc oxide, or a filler material.

Example 11 may include the IC package of example 1 and/or some other examples herein, wherein the underfill material further includes colorants, inhibitors, ion trappers, stress absorbers, polymers, surfactants, binding agents, fluxing agents, or additives.

Example 12 may include the IC package of example 1 and/or some other examples herein, wherein the underfill material is a film, liquid, or powder form before cured on the IC package.

Example 13 may include the IC package of example 1 and/or some other examples herein, wherein the underfill material is applied on the IC package by dispensing, printing, curtain coating, molding, or lamination.

Example 14 may include the IC package of example 1 and/or some other examples herein, wherein the underfill material is located at a logic to logic interconnect, a first level interconnect, a mid-level interconnect, or a PCB level interconnect.

Example 15 may include the IC package of example 1 and/or some other examples herein, wherein the underfill material has a flow distance in a range of about 20 mm to about 50 mm, a flow time in a range of about 10 min to about 30 min, and is stable at a temperature about 150 C.

Example 16 may include the IC package of example 1 and/or some other examples herein, wherein the IC package is a chip scale package (CSP), a wafer-level package (WLP), a multi-chip package (WCP), a quad-flat no-leads (QFN) package, a dual-flat no-leads (DFN) package, a flip chip package, or a ball grid array (BGA) package.

Example 17 may include a method for forming an integrated circuit (IC) package, the method comprising: providing an assembly of the IC package, wherein the assembly includes a first component with a first surface; a second component with a second surface placed opposite to the first surface of the first component to form a space between the first component and the second component; and a connector within the space between the first component and the second component; and providing an underfill material within the space and around the connector, wherein the underfill material includes a resin and a thermolatent onium salt as a cationic cure for the underfill material, wherein the thermolatent onium salt comprises an organic cation with a heteroatom center, and an anion including metalloid fluoride, and wherein the heteroatom center includes an iodonium, sulphonium, phosphonium, or N-containing onium.

Example 18 may include the method of example 17 and/or some other examples herein, wherein the underfill material is a film, liquid, or powder form before cured on the IC package.

Example 19 may include the method of example 17 and/or some other examples herein, wherein providing the underfill material includes dispensing the underfill material, printing the underfill material, curtain coating the underfill material, molding the underfill material, or laminating the underfill material.

Example 20 may include the method of example 17 and/or some other examples herein, wherein the first component or the second component is a printed circuit board (PCB), an interposer, a patch, a packaging substrate, a chip, a die, or a wafer; and the connector is a solder joint, a solder bump, a micro bump, a ball, a contact, a pin, or a through via.

Example 21 may include a computing device, comprising: a first component with a first surface; a second component with a second surface placed opposite to the first surface of the first component to form a space between the first component and the second component; a connector within the space between the first component and the second component; and an underfill material within the space and around the connector, wherein the underfill material includes a resin and a thermolatent onium salt, wherein the thermolatent onium salt comprises an organic cation with a heteroatom center, and an anion including metalloid fluoride, and wherein the heteroatom center includes an iodonium, sulphonium, phosphonium, or N-containing onium.

Example 22 may include the computing device of example 21 and/or some other examples herein, wherein the first component or the second component is a printed circuit board (PCB), an interposer, a patch, a packaging substrate, a chip, a die, or a wafer.

Example 23 may include the computing device of example 21 and/or some other examples herein, wherein the connector is a solder joint, a solder bump, a micro bump, a ball, a pin, a contact, or a through via.

Example 24 may include the computing device of example 21 and/or some other examples herein, wherein the organic cation further includes a benzyl moiety, and the benzyl moiety includes benzylsulfonium, benzylammonium, benzylphosphonium, or benzylpyrazinium; and wherein the anion includes SbF₆, AsF₆, PF₆, or BF₄.

Example 25 may include the computing device of example 21 and/or some other examples herein, wherein the computing device includes a device selected from the group consisting of a wearable device or a mobile computing device, the wearable device or the mobile computing device including one or more of an antenna, a touchscreen controller, a display, a battery, a processor, an audio codec, a video codec, a power amplifier, a global positioning system (GPS) device, a compass, a Geiger counter, an accelerometer, a gyroscope, a speaker, and a camera coupled with the memory device.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. An integrated circuit (IC) package, comprising:
an electronic component; and
an underfill material around or below the electronic component to support the electronic component, wherein the underfill material includes a resin and a thermolatent onium salt as a cationic cure for the underfill material, wherein the thermolatent onium salt comprises an organic cation with a heteroatom center, and an anion including metalloid fluoride, and wherein the heteroatom center includes an iodonium, sulphonium, phosphonium, or N-containing onium.

2. The IC package of claim 1, wherein the organic cation further includes a benzyl moiety.

3. The IC package of claim 2, wherein the benzyl moiety includes benzylsulfonium, benzylammonium, benzylphosphonium, or benzylpyrazinium.

4. The IC package of claim 1, wherein the anion includes SbF₆, AsF₆, PF₆, or BF₄

5. The IC package of claim 1, wherein the thermolatent onium salt includes N-benzylpyrazinium hexafluoroantimonate.

6. The IC package of claim 1, wherein the resin is epoxy resin, acrylates, bismaleimides, polyesters, polyimides, polyolefins, polystyrene, polyurethanes, polyurethane resin, silicone resin, or polyester resin.

7. The IC package of claim 1, wherein the underfill material does not include an amine type hardener, an anhydride type hardener, or a phenol type hardener.

8. The IC package of claim 1, wherein the underfill material includes the thermolatent onium salt with a concentration level greater than or equal to 0.5 wt %.

9. The IC package of claim 1, wherein the underfill material includes Sb, F, As, P, B, or I at a concentration level greater than or equal to 100 ppm.

10. The IC package of claim 1, wherein the underfill material further includes silica, alumina, boron nitride, zinc oxide, or a filler material.

11. The IC package of claim 1, wherein the underfill material further includes colorants, inhibitors, ion trappers, stress absorbers, polymers, surfactants, binding agents, fluxing agents, or additives.

12. The IC package of claim 1, wherein the underfill material is a film, liquid, or powder form before cured on the IC package.

13. The IC package of claim 1, wherein the underfill material is applied on the IC package by dispensing, printing, curtain coating, molding, or lamination.

14. The IC package of claim 1, wherein the underfill material is located at a logic to logic interconnect, a first level interconnect, a mid-level interconnect, or a PCB level interconnect.

15. The IC package of claim 1, wherein the underfill material has a flow distance in a range of about 20 mm to about 50 mm, a flow time in a range of about 10 min to about 30 min, and is stable at a temperature about 150 C.

16. The IC package of claim 1, wherein the IC package is a chip scale package (CSP), a wafer-level package (WLP), a multi-chip package (WCP), a quad-flat no-leads (QFN) package, a dual-flat no-leads (DFN) package, a flip chip package, or a ball grid array (BGA) package.

17. A method for forming an integrated circuit (IC) package, the method comprising:
providing an assembly of the IC package, wherein the assembly includes a first component with a first surface; a second component with a second surface placed opposite to the first surface of the first component to form a space between the first component and the second component; and a connector within the space between the first component and the second component; and
providing an underfill material within the space and around the connector, wherein the underfill material includes a resin and a thermolatent onium salt as a cationic cure for the underfill material, wherein the thermolatent onium salt comprises an organic cation with a heteroatom center, and an anion including metalloid fluoride, and wherein the heteroatom center includes an iodonium, sulphonium, phosphonium, or N-containing onium.

18. The method of claim 17, wherein the underfill material is a film, liquid, or powder form before cured on the IC package.

19. The method of claim 17, wherein providing the underfill material includes dispensing the underfill material, printing the underfill material, curtain coating the underfill material, molding the underfill material, or laminating the underfill material.

20. The method of claim 17, wherein the first component or the second component is a printed circuit board (PCB), an interposer, a patch, a packaging substrate, a chip, a die, or a wafer; and
the connector is a solder joint, a solder bump, a micro bump, a ball, a contact, a pin, or a through via.

21. A computing device, comprising:
a first component with a first surface;
a second component with a second surface placed opposite to the first surface of the first component to form a space between the first component and the second component;
a connector within the space between the first component and the second component; and
an underfill material within the space and around the connector, wherein the underfill material includes a resin and a thermolatent onium salt, wherein the thermolatent onium salt comprises an organic cation with a heteroatom center, and an anion including metalloid fluoride, and wherein the heteroatom center includes an iodonium, sulphonium, phosphonium, or N-containing onium.

22. The computing device of claim 21, wherein the first component or the second component is a printed circuit board (PCB), an interposer, a patch, a packaging substrate, a chip, a die, or a wafer.

23. The computing device of claim 21, wherein the connector is a solder joint, a solder bump, a micro bump, a ball, a pin, a contact, or a through via.

24. The computing device of claim 21, wherein the organic cation further includes a benzyl moiety, and the benzyl moiety includes benzylsulfonium, benzylammonium, benzylphosphonium, or benzylpyrazinium; and
wherein the anion includes SbF₆, AsF₆, PF₆, or BF₄.

25. The computing device of claim 21, wherein the computing device includes a device selected from the group consisting of a wearable device or a mobile computing device, the wearable device or the mobile computing device including one or more of an antenna, a touchscreen controller, a display, a battery, a processor, an audio codec, a video codec, a power amplifier, a global positioning system (GPS) device, a compass, a Geiger counter, an accelerometer, a gyroscope, a speaker, and a camera coupled with the memory device.
